(19) United States
(12) Patent Application Publication
(10) Pub. No.: US 2010/0164026 A1
(43) Pub. Date: Jul. 1, 2010

(54) PREMOLD HOUSING HAVING INTEGRATED VIBRATION ISOLATION

(76) Inventors: Erich Ilich, Unterhausen (DE); Manfred Abendroth, Marbach (DE); Kurt Ingrisch, Reutlingen (DE)

Correspondence Address: KENYON & KENYON LLP, ONE BROADWAY, NEW YORK, NY, 10004, US

(21) Appl. No.: 12/529,917

(22) PCT Filed: Jun. 15, 2007
(86) PCT No.: PCT/EP2007/055974

§ 371 Date: Feb. 4, 2010

(51) Int. Cl. H01L 29/84

(52) U.S. Cl. 257/418; 257/E29.324

(57) ABSTRACT

A premold housing for accommodating a chip structure in which a part of the housing that is connected to the chip structure is connected in a manner that permits elastic deflection to another part of the housing which is attached to the supporting structure bearing the entire housing, the two housing parts not contacting one another.

### FIELD OF THE INVENTION

The present invention relates to a premold housing for accommodating a chip structure, and, more specifically, a chip structure of a micromechanical sensor, having vibration isolation integrated in the housing.

### BACKGROUND INFORMATION

Today, inertial sensors of a micromechanical design for measuring rotation rates or accelerations are a permanent component of active and passive safety systems in motor vehicles. Airbags and vehicle-dynamics control systems constitute other systems. In these systems, there are safety-critical consequences when malfunctions occur due to sensor signals being misinterpreted.

Micromechanical sensors, for example, which are used for various acceleration and motional measurements, must themselves be protected from disturbance accelerations in order to avoid damage or malfunctions. Disturbance accelerations of this kind can act on the particular sensor, particularly when vibration is coupled in by way of insufficiently damped supporting structures.

An unwanted incoupling of vibration is especially problematic when parts of a sensor that is used must themselves be excited at a defined frequency in order to be able to carry out specified measurements. This is the case, for example, when working with rotation-rate sensors, whose function is based on measuring the Coriolis acceleration that occurs in response to the rotation of an oscillating mass. If the disturbance acceleration is coupled in at frequencies which are within the excitation frequency region of such sensors (depending on the sensor type, within the range of between 1 and 30 kHz), there is very significant danger of the sensor signal being misinterpreted.

Therefore, by employing structural design measures, efforts are directed to keeping the influence of disturbance accelerations to a minimum.

These structural design measures include selecting an installation location that is subject to only a minor degree to disturbance accelerations, a vibrationally damped mounting of the module which supports a component that is sensitive to disturbance accelerations, and, optionally, a combination of the two measures. At the present time, the outlay required for a vibrationally damped mounting is relatively high since entire circuit boards or installation units must typically be vibrationally decoupled from the rest of the vehicle. To a certain degree, limiting the installation locations to those subject to minimal disturbance accelerations similarly entails a substantial outlay since it is often not possible or desirable to accommodate the complete module or the entire installation unit at the installation location being considered for placement of the micromechanical sensor. This means that a considerable outlay may be entailed for connections between the actual sensor and the downstream evaluation electronics. Moreover, expensive on-road testing is sometimes required.

When fitted into a housing, e.g., into what is commonly referred to as a premold housing, in the course of a standardized assembly, micromechanical sensors are packaged with prepared contact means that are typically permanently connected to larger circuit structures, for the most part circuit boards, or other supports. Via this connection, disturbance vibrations are coupled into the chip housing and into the chip itself, which is typically connected to a central region of a premold housing in that one side of the chip structure is bonded to a prepared receiving surface. Moreover, special housings for micromechanical measuring elements, for example, welded housing forms of metal (DRS MM1 firm Bosch) have become known. However, the current housing forms are not suited for preventing the incoupling of disturbance accelerations.

### SUMMARY OF INVENTION

Embodiments of the present invention indicate a possibility for reducing the outlay required for protecting sensor elements from disturbance accelerations and, e.g., for automotive applications, to develop additional installation locations for the use of micromechanical sensors.

Embodiments of the present invention provide a premold housing for accommodating a chip structure (2), wherein a part (1) of the housing which is connected to the chip structure (2) is connected in a manner that permits elastic deflection to another part (3) of the housing which is attached to the supporting structure bearing the entire housing, the two housing parts (1, 3) not contacting one another.

Embodiments of the present invention are directed to realizing the functions of conventional components for vibrational decoupling and shock protection with respect to the micromechanical sensor element, e.g., at least partially in the housing of the sensor element. To this end, a premold housing is designed in such a way that the location where the actual sensor element, thus the micromechanical chip structure is to be affixed, is connected via a vibration-decoupling element, which, at the same time, has a damping effect, to the rest of the premold housing, which is connected to a circuit board or a comparable supporting structure. In embodiments of the present invention, in the premold housing, that part of the housing which is connected to the chip structure is connected in a manner that permits elastic deflection to another part of the housing, which is attached to the supporting structure bearing the entire housing, with the aid of an elastically deformable medium in such a way that both housing parts do not contact one another. Along the lines of the present invention, an elastically deformable medium is understood to be any material whose adhesiveness is suited for permanently joining together the housing parts, and whose elastic and damping volume properties make possible the deflection capability according to an embodiment of the present invention, given sufficient damping of relative movements between the housing parts.

That part of the housing which is connected to the chip structure includes a bottom plate, which is connected via an elastically deformable medium to another part of the housing surrounding the bottom plate in a frame shape that is attached to the supporting structure bearing the entire housing. The chip structure to be accommodated is affixed to the bottom plate. By properly selecting the distance between the edge of the bottom plate and the other part of the housing surrounding the bottom plate in a frame shape, it may be ensured that the two housing parts do not contact one another, even during the relative movements between the two housing parts which may occur during typical disturbance accelerations.

Embodiments of the present invention include that the elastically deformable medium contains silicon or is made entirely of silicon. Embodiments of the present invention provide that the elastically deformable medium fills the intermediate space between the bottom plate and the part of the housing surrounding the bottom plate in a frame shape. An especially effective vibrational decoupling is able to be realized when the elastically deformable medium is located in the intermediate space between the bottom plate and the part of the housing surrounding the bottom plate in a frame shape, the thickness of the elastically deformable medium not being greater than the thickness of the bottom plate. In an embodiment, at the least, the elastically deformable medium has a distribution that ensures that the elastically deformable medium is essentially subject to a shearing stress in response to a deflection of the bottom plate orthogonally to the plane of extension thereof.

In embodiments of the present invention, that part of the housing which is connected to the chip structure is additionally provided with ballast. In this manner, the total mass of the assembly to be deflected may be influenced in order to adapt the system functioning as a mechanical low pass to disturbance accelerations to be expected, by defining its cutoff frequency.

In embodiments of the present invention, this adaptation may be undertaken when the bottom plate is joined to a ballast plate. In this manner, bottom plates having essentially the same shape may be stocked for different chip assemblies and decoupling configurations by providing these bottom plates with different ballast plates.

In embodiments of the present invention, the relative movements to be expected between the two housing parts are advantageously limited to a degree that allows a micromechanical sensor chip, which is attached to the bottom plate, to be connected via bond connections to a lead frame that is located on the part of the housing surrounding the bottom plate in a frame shape, without overstressing the bond connection.

In embodiments of the present invention, at least one ASIC chip for evaluating the signals of the micromechanical sensor chip may be attached to the bottom plate, which ASIC chip is likewise connected via bond connections to the lead frame that is located on the part of the housing surrounding the bottom plate in a frame shape.

The connection between this ASIC chip and the micromechanical sensor chip may likewise be implemented via bond connections. In one design of the deflectable housing part as a bottom plate, including the ballast plate, a desired total mass may be readily adapted to different chip structures, without having to implement changes to the housing design in terms of attachment technology.

### BRIEF DESCRIPTION OF THE DRAWINGS

FIG. 1 shows an amplitude transfer function of a system according to embodiments of the present invention for isolating vibrations.

FIG. 2 shows a sectional representation of a premold housing according to embodiments of the present invention.

### DETAILED DESCRIPTION

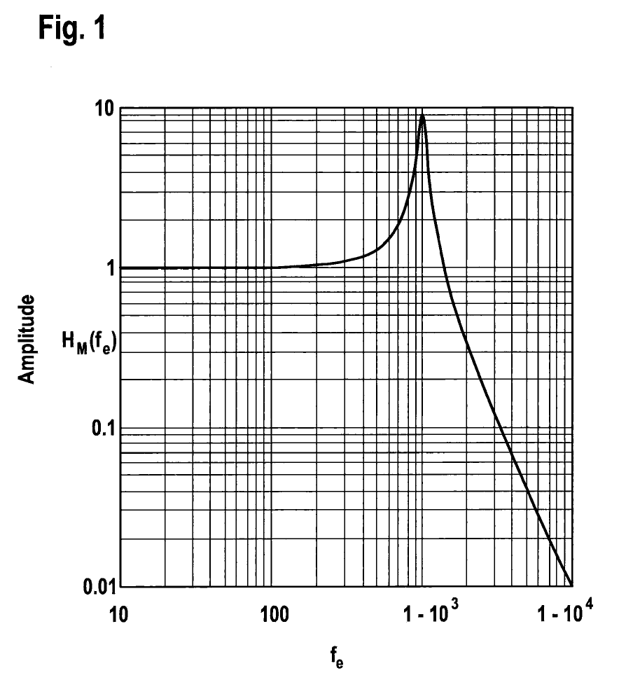

FIG. 1 shows an amplitude transfer function of a system according to the present invention for isolating vibrations. It maps ratio H_{M}(fe) of the vibrational amplitudes of the two housing parts as a function of frequency fe of the disturbance acceleration measured in Hz. In the low-frequency region, its value is essentially near 1. This means that incoupled vibrations are transmitted undamped through the system. In an embodiment, a vibrational isolation does not occur since, at the low frequencies, the disturbance accelerations are too low to appreciably deform the elastically deformable medium. In response to an increase in the frequency of the incoupled vibration, the amplitude with which the deflectable module, thus the bottom plate including the chip structure that is to be actually protected from vibrations, moves, becomes greater than the amplitude of the module that couples in the vibration, thus of the outer housing part. At resonance frequency, the amplitude of the bottom plate reaches a maximum, which represents the worst case in a vibrational isolation system. The resonance frequency is dependent on the deflected mass and the spring constant of the elastically deformable system. A further increase in the frequency leads to a continuous reduction in the transmitted amplitude, which, in this manner, may be brought significantly below the amplitude of the incoupled vibrations. In this manner, the vibrational isolation becomes effective above a specific frequency. An incoupling of disturbance acceleration having components which are substantially higher in frequency than the resonance frequency, is no longer possible.

In embodiments of the present invention, a configuration according to the present invention that is dimensioned in such a way that its resonance frequency is approximately 1 kHz; at 10 kHz, only still transmits approximately 1% of the disturbance amplitude to the chip structure to be protected. Thus, this type of housing design would be well suited for accommodating Coriolis sensors, for example, whose oscillator frequency is above 10 kHz, since such a superimposition with a disturbance vibration of a similar frequency is virtually negligible.

The requisite degree of damping of vibrations of the particular frequency regions depends on the sensors used and the measuring tasks thereof. However, it may be adjusted with the aid of the premold housing according to the present invention, while entailing very little outlay.

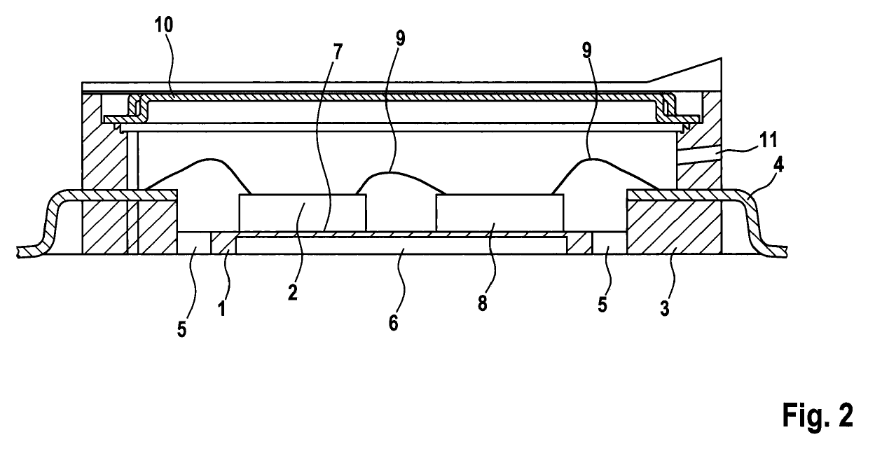

FIG. 2 shows a sectional representation of a premold housing according to the present invention. The housing is composed of two housing parts of which one first part is designed in the form of a bottom plate 1 and is used for accommodating chip structure 2 which is to be protected from disturbance accelerations.

Second housing part 3 has a corresponding lead frame which includes legs 4 that project laterally out of the housing and facilitate a soldered connection to a circuit board (not shown), through which means the attachment to a supporting structure bearing the entire housing is realized exemplarily along the lines of the present invention. However, the precise geometry of the attachment means does not play a role in the understanding of the present invention. What is significant is that the connection between second housing part 3 and, in this case, the circuit board may be of such rigidity that vibrations of the circuit board are completely transmitted to second housing part 3. Second housing part 3 surrounds bottom plate 1 in a frame shape; between the two housing parts, a space remaining which ensures that bottom plate 1 does not contact second housing part 3, even during the relative movements between the two housing parts 1, 3 which may occur during typical disturbance accelerations.

The intermediate space that defines this space between the outer edge of bottom plate 1 and part 3 of the housing surrounding bottom plate 1 in a frame shape is filled with a silicon (LSR liquid silicon rubber) which constitutes an elastically deformable medium 5 and, at the same time, due to its superior adhesive properties, is used for attaching bottom plate 1 to second housing part 3. The thickness of silicon 5 corresponds approximately to that of bottom plate 1 in the region of contact with silicon 5. Thus, elastically deformable medium 5 has a distribution which ensures that elastically deformable medium 5 is essentially initially subject to a shearing stress in response to a deflection of bottom plate 1 orthogonally to the plane of extension thereof.

At its bottom side, bottom plate 1 is joined to a ballast plate 6. On its top side, it is joined via adhesive layers 7 to a sensor chip 2 and an ASIC chip 8 which is used for a first analysis of the signals supplied by sensor chip 2. Both chips 2, 8 are connected via bond connections 9 to the lead frame and to one another.

Bottom plate 1, ballast plate 6 and the two chips 2, 8 form a deflectable mass which co-determines the cutoff frequency of the system functioning as a mechanical low pass. In addition, this cutoff frequency is a function of the spring constant of the elastically deformable system which, in the present case, is composed of silicon filling 5 in the intermediate space between the two housing parts 1, 3. The cutoff frequency of the system that functions as a mechanical low pass may be adapted to disturbance accelerations to be expected by varying the mass of ballast plate 6, by varying the cross sectional geometry of silicon filling 5, as well as by varying the material properties of silicon 5, in the broader sense of the elastically deformable medium, by an appropriate material selection.

The top side of the housing is sealed with a cap 10 that is located at a sufficient distance from the deflectable module on bottom plate 1 in order to ensure contact freedom at all times.

In a further embodiment, bottom plate 1 is injected with the aid of silicon 5 into frame-shaped second housing part 3, thereby forming an airtight connection between two housing parts 1, 3. To avoid intrinsic movements of bottom plate 1 caused by pressure changes, for example, in response to temperature changes, the housing has a small bore 11 in order to render possible a pressure compensation at any time.

In the housing design, it is easily possible to slightly vary the precise height at which bottom plate 1 is inserted into second housing part 3. Thus, bonding technology requirements may be considered with regard to the bonding angles to be preferred. The relative movements to be expected between the two housing parts 1, 3 may remain limited to a degree that hardly stresses the bond connections, even in the case of a relatively substantial travel.

As described above, it is often necessary in automotive applications to keep relatively low-frequency disturbance accelerations away from sensitive structures. To this end, in spite of the very low masses of numerous chips, low resonance frequencies of the assembly are required, which is assisted in accordance with the present invention by increasing the mass of the deflectable module through the use of a ballast plate 6, but also by configuring other, less disturbance-sensitive chips 8 on a common bottom plate 1. To render possible the very small spring constants of the elastically deformable system that are required in spite of these measures, without having to resort to very filigreed and thus fracture-prone spring structures, the present invention provides, in the first case, for a material having a low modulus of elasticity to be used, and, secondly, for a cross sectional design to be selected, which largely subjects this material to a shearing stress, but avoids tensile and compressive stresses against which it offers a substantially higher resistance. Thus, even when working with a voluminous, elastically deformable system, the desired low resonance frequencies may also be achieved in response to excitations that occur orthogonally to the plane of extension of bottom plate 1. The adaptation of the restoring forces in parallel to the bottom plate is carried out by a correspondingly smaller dimensioning of the cross section of elastically deformable medium 5.

1-10. (canceled)

11. A premold housing for accommodating a chip structure, comprising:
a part of the housing, the part being connected to the chip structure and connected in a manner that permits elastic deflection to another part of the housing attached to the supporting structure bearing the entire housing, wherein the two housing parts do not contact each other.

12. The premold housing as recited in claim 11,
wherein that part of the housing which is connected to the chip structure includes a bottom plate, which is connected via an elastically deformable medium to another part of the housing surrounding the bottom plate in a frame shape that is attached to the supporting structure bearing the entire housing.

13. The premold housing as recited in claim 12, wherein the elastically deformable medium includes silicon.

14. The premold housing as recited in claim 12, wherein the elastically deformable medium fills the intermediate space between the bottom plate and the part of the housing surrounding the bottom plate in a frame shape.

15. The premold housing as recited in clam 12, wherein the elastically deformable medium is located in the intermediate space between the bottom plate and the part of the housing surrounding the bottom plate in a frame shape, the thickness of the elastically deformable medium not being greater than the thickness of the bottom plate.

16. The premold housing as recited in claim 12, wherein the elastically deformable medium has a distribution such that the elastically deformable medium is essentially subject to a shearing stress in response to a deflection of the bottom plate orthogonally to the plane of extension thereof.

17. The premold housing as recited in claim 11, wherein that part of the housing which is connected to the chip structure is provided with ballast.

18. The premold housing as recited in claim 12, wherein the bottom plate is joined to a ballast plate.

19. The premold housing as recited in claim 12, wherein a micromechanical sensor chip, which is attached to the bottom plate, is connected via bond connections to a lead frame that is located on the part of the housing surrounding the bottom plate in a frame shape.

20. The premold housing as recited in claim 19, wherein, attached to the bottom plate is an ASIC chip for evaluating the signals of the micromechanical sensor chip which is connected via bond connections to the lead frame that is located on the part of the housing surrounding the bottom plate in a frame shape, and is connected to the micromechanical sensor chip.
